(19) United States
(12) Patent Application Publication
(10) Pub. No.: US 2011/0018049 A1
(43) Pub. Date: Jan. 27, 2011

(54) Charge trapping device and method for manufacturing the same

(75) Inventors: Kuei-Shu Chang-Liao, Hsinchu City (TW); Pei-Jer Tzeng, Hsinchu City (TW); Chu-Yung Liu, Hsinchu City (TW); Zong-Hao Ye, Hsinchu City (TW); Ping-Hung Tsai, Hsinchu City (TW); Te-Chiang Liu, Hsinchu City (TW)

Correspondence Address: BACON & THOMAS, PLLC, 625 SLATERS LANE, FOURTH FLOOR, ALEXANDRIA, VA, 22314-1176, US

(73) Assignee: National Tsing Hua University, Hsinchu (TW)

(21) Appl. No.: 12/591,763

(22) Filed: Dec. 1, 2009

(30) Foreign Application Priority Data
Jul. 22, 2009 (TW) 098124696

(51) Int. Cl. H01L 29/792; H01L 21/28

(52) U.S. Cl. 257/324; 438/591; 257/E29.309; 257/E21.21

(57) ABSTRACT

The present invention relates to a charge trapping device and a method for manufacturing the same. The charge trapping device includes: a substrate having a first surface and an opposite second surface; a tunneling insulating layer, disposed on the first surface of the substrate; a charge trapping layer, disposed on the tunneling insulating layer and including a first dielectric layer and a second dielectric layer, in which the first dielectric layer is connected to the tunneling insulating layer, the second dielectric layer is disposed over the first dielectric layer, and a conduction band offset between the first dielectric layer and the substrate is larger than that between the second dielectric layer and the substrate; and a blocking insulating layer, disposed on the charge trapping layer and connected to the second dielectric layer. Accordingly, the charge trapping device of the present invention has excellent programming, and erasing and charge retention properties.

### BACKGROUND OF THE INVENTION

1. Field of the Invention

The present invention relates to a charge trapping device and a method for manufacturing the same and, more particularly, to a charge trapping device suitable for being applied in a flash memory device and a method for manufacturing the same.

2. Description of Related Art

A flash memory device is one of the indispensable components in current electronic systems. A flash memory device is widely applied due to its large capacity, miniature size, non-volatility, low-power consumption, low cost, and recordable/rewritable characteristics. Particularly, flash memory devices are suitable for being applied in portable electronic products, such as cell phones, digital cameras, USB and so on.

Flash memory devices can be largely classified into floating gate type flash memory devices and polysilicon-oxide-nitride-silicon (SONOS) type flash memory devices. With reference to FIG. 1, there is shown a cross sectional view of a conventional floating gate type flash memory device. As shown in FIG. 1, the floating gate type flash memory device mainly includes: a substrate 11, having a source 111 and a drain 112; a tunneling insulating layer 12, located on the substrate 11; a floating gate 13, located on the tunneling insulating layer 12; a dielectric layer 14, located on the floating gate 13; and a control gate 15, located on the dielectric layer 14. Herein, the floating gate 13 is used for trapping charge and is made of polysilicon, and the dielectric layer 14 has a bottom oxide-nitride-top oxide (ONO) structure in which an oxide layer 141, a nitride layer 143 and an oxide layer 143 are laminated in sequence.

SONOS type flash memory devices directly use the ONO dielectric layer between the floating gate and the control gate as a memory unit. FIG. 2 shows a cross sectional view of a SONOS type flash memory device. As shown in FIG. 2, the SONOS flash memory device mainly includes: a substrate 21, having a source 211 and a drain 212; a tunneling insulating layer 22, located on the substrate 21; a charge trapping layer 23, located on the tunneling insulating layer 22; a blocking insulating layer 24, located on the charge trapping layer 23; and a control gate 25, located on the blocking insulating layer 24. Herein, the tunneling insulating layer 22 mainly functions for inhibiting the loss of the trapped charge after programming, the charge trapping layer 23 is used for trapping charge, and the blocking insulating layer 24 is provided for blocking the charge flow between the charge trapping layer 23 and the control gate 25.

So far, many researchers have made efforts in developing flash memory devices with improved operation characteristics and charge retention. However, these flash memory devices generally use a single-layered silicon nitride layer as a charge trapping layer, and few reports centre on the modification of the charge trapping layer.

### SUMMARY OF THE INVENTION

The object of the present invention is to provide a charge trapping device that has excellent programming, and erasing and charge retention properties. Accordingly, it can be applied in a flash memory device to present improved operation characteristics and excellent charge retention and thus enhanced performance.

To achieve the object, the present invention provides a charge trapping device, comprising: a substrate, having a first surface and an opposite second surface; a tunneling insulating layer, disposed on the first surface of the substrate; a charge trapping layer, disposed on the tunneling insulating layer and including a first dielectric layer and a second dielectric layer, in which the first dielectric layer is connected to the tunneling insulating layer, the second dielectric layer is disposed over the first dielectric layer, and a conduction band offset between the first dielectric layer and the substrate is larger than that between the second dielectric layer and the substrate; and a blocking insulating layer, disposed on the charge trapping layer and connected to the second dielectric layer.

Accordingly, through the stacked type charge trapping layer, the present invention can improve the operation characteristics including programming and erasing and presents excellent charge retention. Particularly, regarding the charge trapping layer of the present invention, a dielectric layer with a smaller conduction band offset is stacked after a dielectric layer with a larger conduction band offset, and thereby the programming speed and erasing speed can be simultaneously enhanced. Therefore, the situation observed in conventional charge trapping devices that the programming speed is large while the erasing speed is small can be improved.

In the charge trapping device according to the present invention, the materials of the first dielectric layer and the second dielectric layer may be any conventional high-k material, such as silicon nitride, hafnium oxide, hafnium aluminum oxide and hafnium silicate. Preferably, the material of the first dielectric layer is silicon nitride, hafnium oxide, hafnium aluminum oxide or hafnium silicate, and the material of the second dielectric layer is hafnium oxide, hafnium aluminum oxide or hafnium silicate. More preferably, the materials of the first dielectric layer and the second dielectric layer respectively are silicon nitride and hafnium oxide; hafnium aluminum oxide and hafnium oxide; hafnium oxide and hafnium silicate; hafnium aluminum oxide and hafnium aluminum oxide, in which the aluminum/hafnium ratio of the first dielectric layer is larger than that of the second dielectric layer; or hafnium silicate and hafnium silicate, in which the silicon/hafnium ratio of the first dielectric layer is smaller than that of the second dielectric layer.

In the charge trapping device according to the present invention, the substrate may be an Si substrate, and in more detail may be a P-type Si substrate. Additionally, the substrate may have a source and a drain.

In the charge trapping device according to the present invention, the material of the tunneling insulating layer may be any conventional material used in a tunneling insulating layer, such as silicon oxide, aluminum oxide, hafnium aluminum oxide and so on.

In the charge trapping device according to the present invention, the material of the blocking insulating layer may be any conventional material used in a blocking insulating layer, such as silicon oxide, aluminum oxide, hafnium aluminum oxide and so on.

The charge trapping device according to the present invention may further comprise a control gate disposed on the blocking insulating layer. Herein, the material of the control gate can be any conventional material used in a control gate, such as tantalum nitride, molybdenum nitride and so on.

The charge trapping device according to the present invention may further comprise a first electrode and a second electrode respectively connected to the control gate and the second surface of the substrate. Herein, the materials of the first electrode and the second electrode may be any electrode material, such as Al—Si—Cu, Al and so on.

Moreover, the present invention further provides a method for manufacturing the above-mentioned charge trapping device, comprising: providing a substrate having a first surface and an opposite second surface; forming a tunneling insulating layer on the first surface of the substrate; forming a charge trapping layer on the tunneling insulating layer, wherein the charge trapping layer includes a first dielectric layer and a second dielectric layer, the first dielectric layer is connected to the tunneling insulating layer, the second dielectric layer is disposed over the first dielectric layer, and a conduction band offset between the first dielectric layer and the substrate is larger than that between the second dielectric layer and the substrate; and forming a blocking insulating layer on the charge trapping layer, wherein the blocking insulating layer is connected to the second dielectric layer.

The method of the present invention may further comprise: forming a control gate on the blocking insulating layer.

The method of the present invention may further comprise: respectively forming a first electrode and a second electrode on the control gate and the second surface of the substrate.

In the method according to the present invention, the charge trapping layer may be formed by chemical vapor deposition, such as atomic layer deposition (ALD), metal organic chemical vapor deposition (MOCVD) and low pressure chemical vapor deposition (LPCVD).

In conclusion, the charge trapping layer of the charge trapping device according to the present invention has a stacked type structure, in which a dielectric layer with a smaller conduction band offset is stacked after a dielectric layer with a larger conduction band offset. Accordingly, in comparison with a conventional single-layered charge trapping layer, the present invention can simultaneously enhance programming speed and erasing speed of the charge trapping device, and present excellent charge retention.

Other objects, advantages, and novel features of the invention will become more apparent from the following detailed description when taken in conjunction with the accompanying drawings.

### BRIEF DESCRIPTION OF THE DRAWINGS

FIG. 1 is a cross sectional view of a conventional floating gate type flash memory device;

FIG. 2 is a cross sectional view of a polysilicon-oxide-nitride-silicon type flash memory device;

FIGS. 3A to 3G are cross sectional views for illustrating a method for manufacturing a charge trapping device according to one preferred embodiment of the present invention;

FIG. 4 is an energy band diagram for the charge trapping device according to Embodiment 1 of the present invention;

FIG. 5 is an energy band diagram for the charge trapping device according to Embodiment 2 of the present invention;

FIG. 6 is an energy band diagram for the charge trapping device according to Embodiment 3 of the present invention;

FIG. 7 is an energy band diagram for the charge trapping device according to Embodiment 4 of the present invention;

FIG. 8 is a flat-band voltage shift vs. programming time diagram by F-N of 8V (-▪- for Embodiment 1, -- for Comparative Embodiment 1, -▴- for Comparative Embodiment 2);

FIG. 9 is a flat-band voltage shift vs. erasing time diagram by F-N of −8V (-▪- for Embodiment 1, -- for Comparative Embodiment 1, -▴- for Comparative Embodiment 2);

FIG. 10 is a flat-band voltage shift (%) vs. time diagram (-▪- for Embodiment 1, -- for Comparative Embodiment 1, -▴- for Comparative Embodiment 2);

FIG. 11 is a flat-band voltage shift vs. programming time diagram by F-N of 10V (-□- for Embodiment 2, -◯- for Embodiment 3, -▴- for Comparative Embodiment 3, -▪- for Comparative Embodiment 4, -- for Comparative Embodiment 5);

FIG. 12 is a flat-band voltage shift vs. erasing time diagram by F-N of −10V (-□- for Embodiment 2, -◯- for Embodiment 3, -▴- for Comparative Embodiment 3, -▪- for Comparative Embodiment 4, -- for Comparative Embodiment 5);

FIG. 13 is a flat-band voltage shift (%) vs. time diagram (-□- for Embodiment 2, -◯- for Embodiment 3, -▴- for Comparative Embodiment 3, -▪- for Comparative Embodiment 4, -- for Comparative Embodiment 5);

FIG. 14 is a flat-band voltage shift vs. programming time diagram by F-N of 10V (-- for Embodiment 4, -▴- for Comparative Embodiment 6);

FIG. 15 is a flat-band voltage shift vs. erasing time diagram by F-N of −10V (-- for Embodiment 4, -▴- for Comparative Embodiment 6); and

FIG. 16 is a flat-band voltage shift (%) vs. time diagram (-- for Embodiment 4, -▴- for Comparative Embodiment 6).

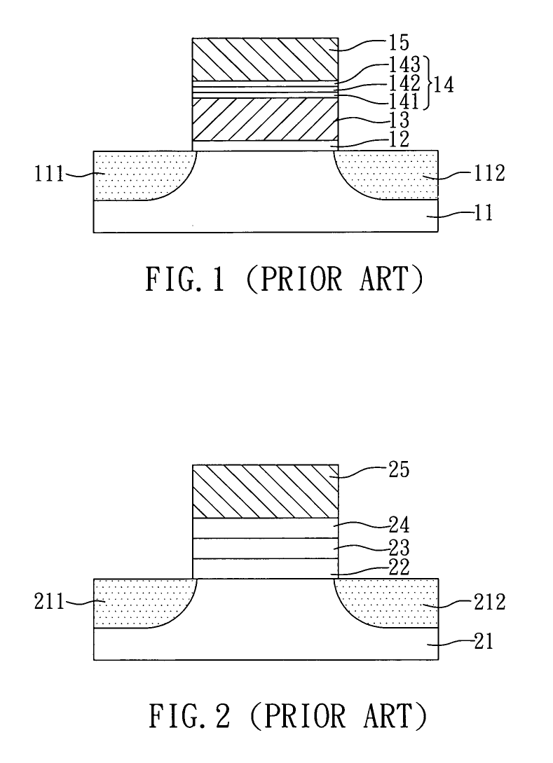

### DETAILED DESCRIPTION OF THE PREFERRED EMBODIMENT

### Embodiment 1

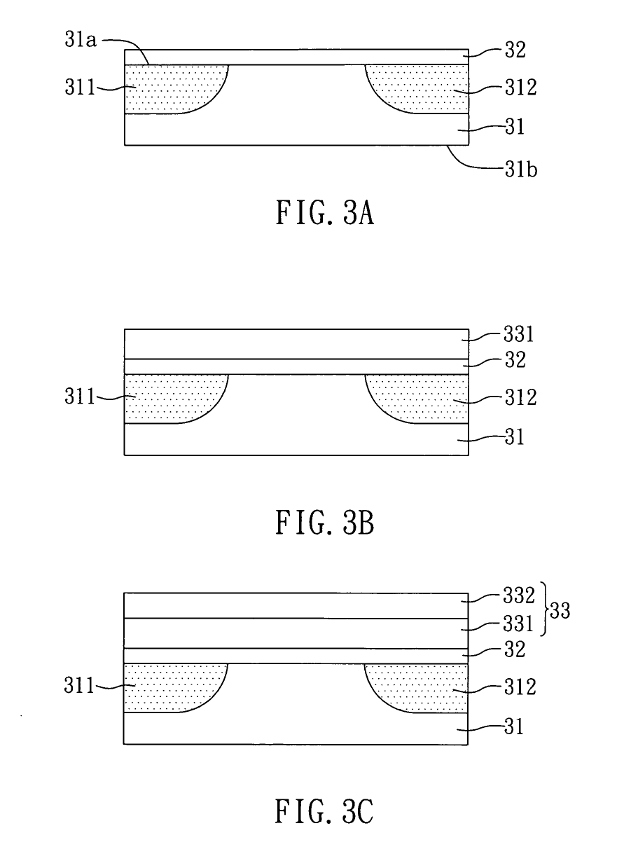

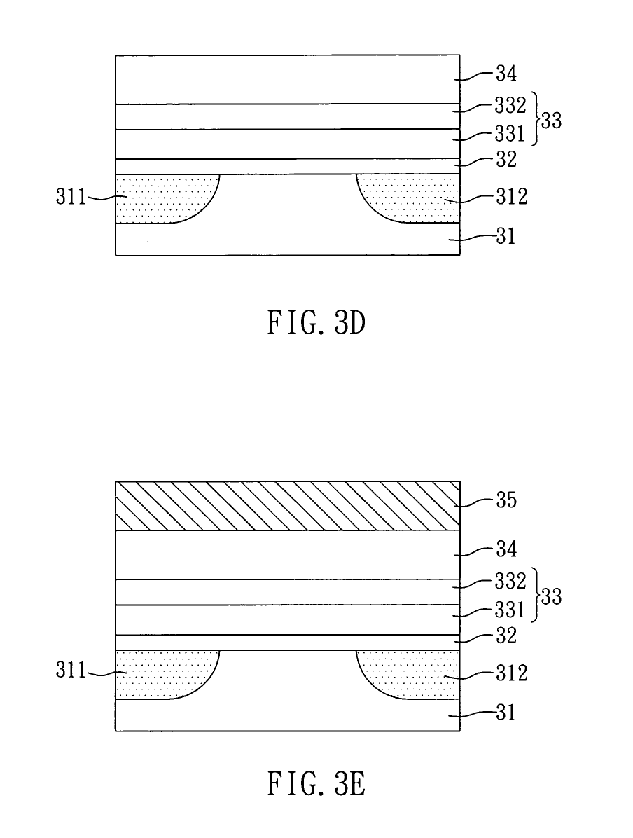

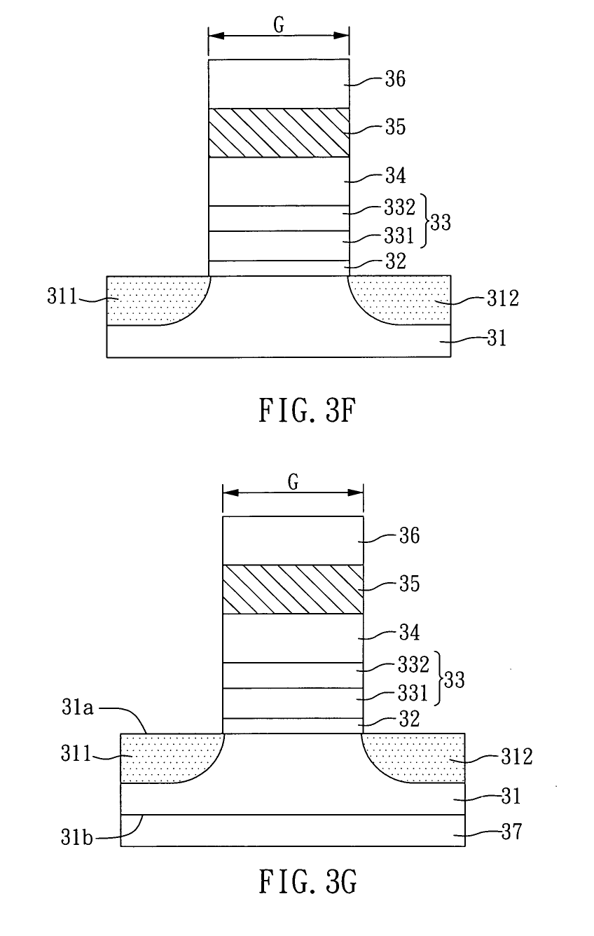

With reference to FIGS. 3A to 3G, there are shown cross sectional views for illustrating a method for manufacturing a charge trapping device according to the present embodiment. As shown in FIG. 3A, through a vertical furnace, a tunneling insulating layer 32 is formed on a first surface 31a of a substrate 31. Herein, the substrate 31 is a P-type Si substrate having a source 311 and a drain 312, and the tunneling insulating layer 32 is made of silicon oxide in a thickness of 30 angstrom.

Subsequently, as shown in FIG. 3B, through a horizontal furnace, a first dielectric layer 331 is deposited on the tunneling insulating layer 32. Herein, the material of the first dielectric layer 331 is silicon nitride and its thickness is 50 angstrom. As shown in FIG. 3C, a second dielectric layer 332 is deposited on the first dielectric layer 331 by a metal organic chemical vapor deposition system. Herein, the second dielectric layer 332 is made of hafnium oxide and its thickness 30 angstrom. In the present embodiment, the stacked first dielectric layer 331 and second dielectric layer 332 are used as a charge trapping layer 33 of the charge trapping device.

Then, as shown in FIG. 3D, a blocking insulating layer 34 is deposited on the charge trapping layer 33 through a metal organic chemical vapor deposition system. Herein, the material of the blocking insulating layer 34 is aluminum oxide and its thickness is 150 angstrom. Next, as shown in FIG. 3E, through a sputtering system, a control gate 35 is formed on the blocking insulating layer 34, and then a thermal annealing process is performed at 900° C. for 30 seconds. Herein, the control gate 35 is made of TaN in a thickness of 1000 angstrom. Subsequently, as shown in FIG. 3F, a first electrode 36 is formed on the control gate 35 by a sputtering system, followed by photoresist coating, exposure and then development through a G-line stepper and an automated photoresist coating and developing system (Track). Then, an etching process is performed through a metal etcher to define a gate region G. Herein, the first electrode 36 is made of Al—Si—Cu in a thickness of 3000 angstrom.

Finally, as shown in FIG. 3G, a second electrode 37 is formed on the second surface 31b of the substrate 31 through a sputtering system, followed by sintering at 450° C. for 30 minutes, so as to accomplish the charge trapping device as shown in FIG. 3G. Herein, the material of the second electrode 37 is Al—Si—Cu, and its thickness is 5000 angstrom.

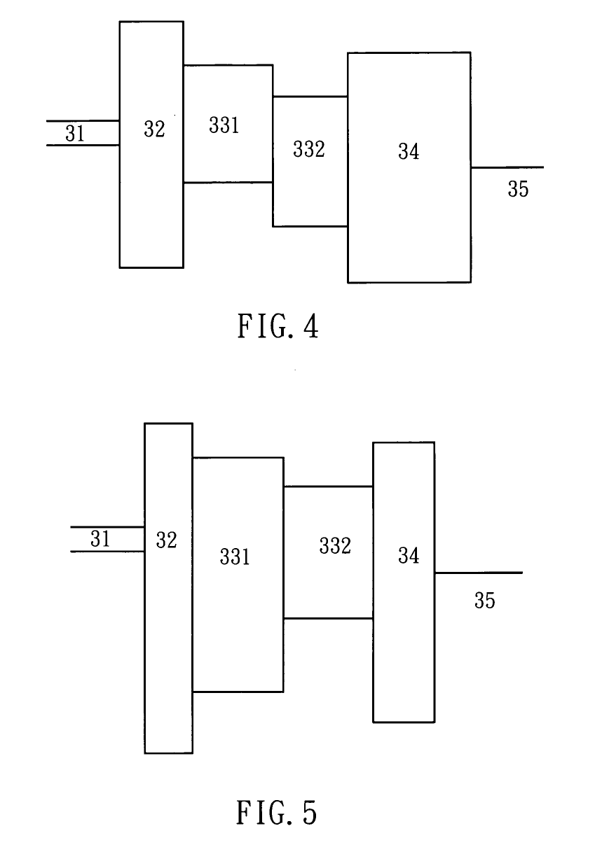

With reference to FIG. 4, there is shown an energy band diagram for the charge trapping device according to the present embodiment. As shown in FIG. 4, in the charge trapping device according to the present embodiment, the conduction band offset between the first dielectric layer 331 and the substrate 31 is larger than that between the second dielectric layer 332 and the substrate 31.

Accordingly, as shown in FIG. 3G, the present embodiment provides a charge trapping device that includes: a substrate 31, having a first surface 31a and an opposite second surface 31b; a tunneling insulating layer 32, disposed on the first surface 31a of the substrate 31; a charge trapping layer 33, disposed on the tunneling insulating layer 32 and including a first dielectric layer 331 and a second dielectric layer 332, in which the first dielectric layer 331 is connected to the tunneling insulating layer 32, the second dielectric layer 332 is disposed over the first dielectric layer 331, and a conduction band offset between the first dielectric layer 331 and the substrate 31 is larger than that between the second dielectric layer 332 and the substrate 31; a blocking insulating layer 34, disposed on the charge trapping layer 33 and connected to the second dielectric layer 332; a control gate 35, disposed on the blocking insulating layer 34; and a first electrode 36 and a second electrode 37, respectively disposed on the control gate 35 and the second surface 31b of the substrate 31.

### Embodiment 2-4

The method for manufacturing the charge trapping devices according to Embodiments 2 to 4 is the same as that described in Embodiment 1, except that the charge trapping layer conditions according to Embodiments 2 to 4 are shown in Table 1 and the charge trapping layer and the blocking insulating layer according to Embodiments 2 to 4 are formed through atomic layer deposition (ALD).

TABLE 1

| | Charge Trapping Layer | |
|---|---|---|
| | First Dielectric Layer | Second Dielectric Layer |
| Embodiment | (constitute ratio, thickness) | (constitute ratio, thickness) |
| 2 | hafnium aluminum oxide | hafnium oxide |
| | (Hf/Al = 1/4, 30 angstrom) | (30 angstrom) |
| 3 | hafnium aluminum oxide | hafnium aluminum oxide |
| | (Hf/Al = 1/4, 30 angstrom) | (Hf/Al = 1/1, 30 angstrom) |
| 4 | hafnium oxide | hafnium silicate |
| | (30 angstrom) | (Hf/Si = 2/1, 30 angstrom) |

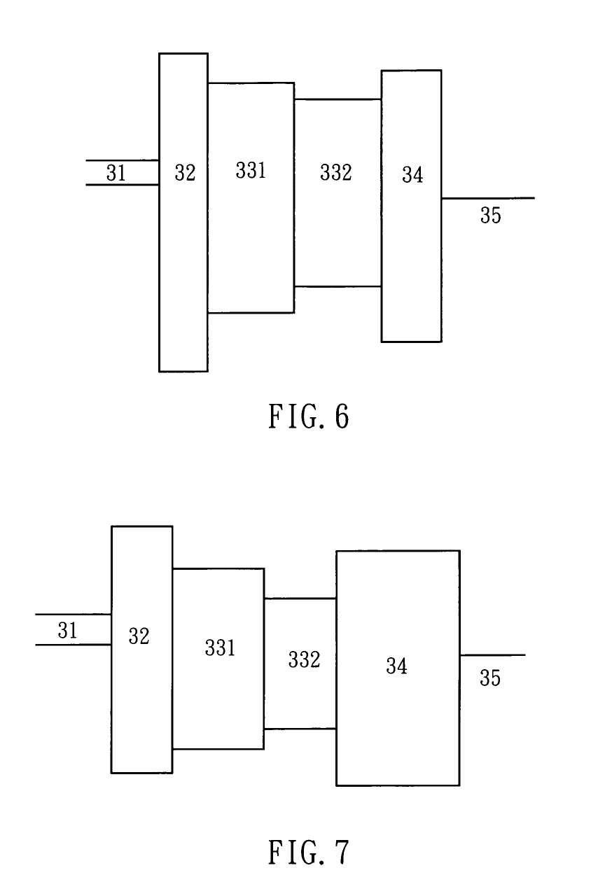

Please refer to FIGS. 5, 6 and 7, which respectively show energy band diagrams of the charge trapping devices according to Embodiments 2, 3 and 4. As shown in FIGS. 5, 6 and 7, in the charge trapping devices according to Embodiments 2, 3 and 4, the conduction band offset between the first dielectric layer 331 and the substrate 31 is larger than that between the second dielectric layer 332 and the substrate 31.

### Comparative Embodiments 1-2

The structures and the manufacturing methods of the charge trapping devices according to Comparative Embodiments 1 and 2 are the same as those described in Embodiment 1, except that the charge trapping layer according to Comparative Embodiments 1 and 2 is in a single-layered structure, the charge trapping layer in Comparative Embodiment 1 is made of silicon nitride in a thickness of 80 angstrom by a horizontal furnace, and charge trapping layer in Comparative Embodiment 2 is made of hafnium oxide in a thickness of 60 angstrom by a metal organic chemical vapor deposition system.

### Comparative Embodiments 3-6

The structures and the manufacturing methods of the charge trapping devices according to Comparative Embodiments 3 to 6 are the same as those described in Embodiments 2 to 4, except that the charge trapping layer conditions according to Comparative Embodiments 3 to 6 are shown in Table 2, in which the charge trapping layer according to Comparative Embodiments 4-6 is in a single-layered structure, and the two-layered structure of the charge trapping layer according to Comparative Embodiment 3 is formed by stacking a dielectric layer with a smaller conduction band offset and then a dielectric layer with a larger conduction band offset.

TABLE 2

| | Charge Trapping Layer | |
|---|---|---|
| Comparative | First Dielectric Layer | Second Dielectric Layer |
| Embodiment | (constitute ratio, thickness) | (constitute ratio, thickness) |
| 3 | hafnium oxide | hafnium aluminum oxide |
| | (30 angstrom) | (Hf/Al = 1/4, 30 angstrom) |

| | |
|---|---|
| 4 | hafnium oxide |
| | (60 angstrom) |
| 5 | hafnium aluminum oxide |
| | (Hf/Al = 1/4, 60 angstrom) |
| 6 | hafnium silicate |
| | (Hf/Si = 2/1, 60 angstrom) |

### Experimental Embodiment 1

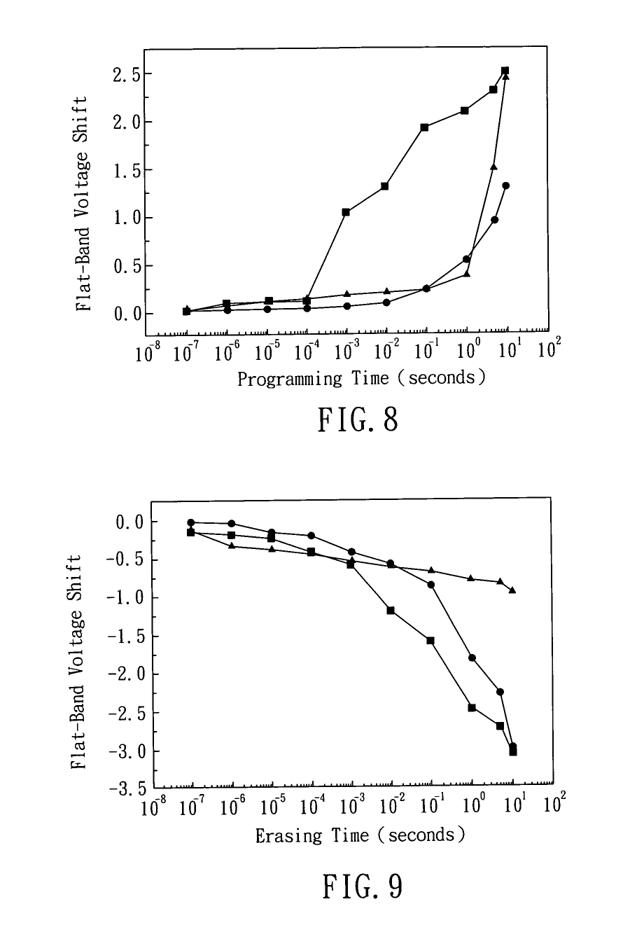

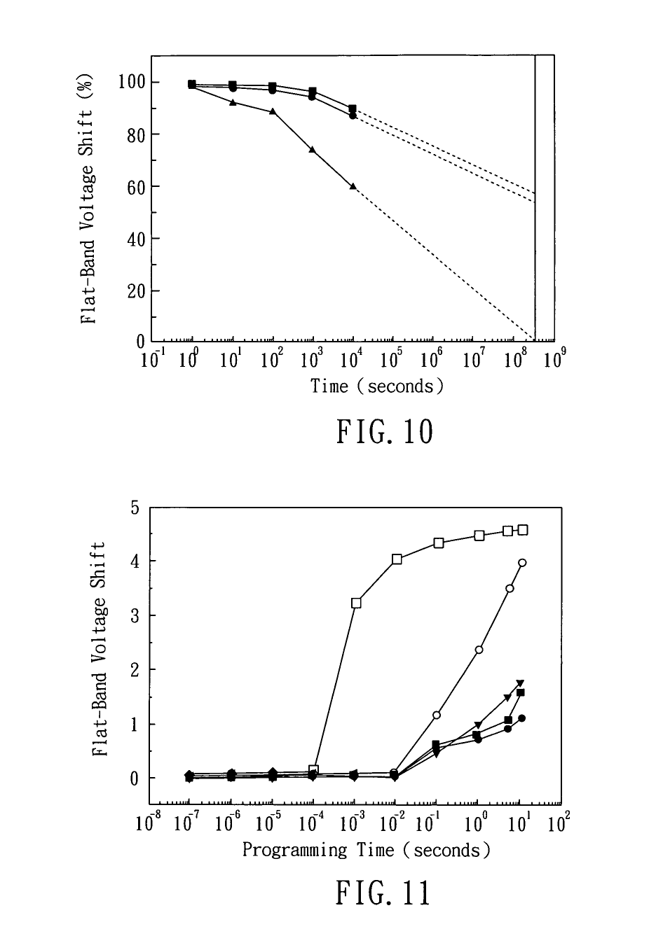

The charge trapping devices according to Embodiment 1 and Comparative Embodiments 1 and 2 are operated by channel Fowler-Nordheim (F-N) programming/erasing and the flat-band voltage shift (ΔVfb) is measured so as to evaluate the operation characteristics and charge retention of the charge trapping devices according to Embodiment 1 and Comparative Embodiments 0.1 and 2. FIGS. 8, 9 and 10 respectively show a flat-band voltage shift vs. programming time diagram by F-N of 8V, a flat-band voltage shift vs. erasing time diagram by F-N of −8V, and a flat-band voltage shift (%) vs. time diagram.

From the results shown in FIGS. 8 to 10, it can be confirmed that the charge trapping device according to Embodiment 1 exhibits improved programming, and erasing and charge retention characteristics in comparison with those according to Comparative Embodiments 1 and 2. In addition, based on the tunneling theory, a charge trapping device with higher programming speed generally presents lower erasing speed. As shown in the curves for Comparative Embodiments 1 and 2 in FIGS. 8 and 9, Comparative Embodiment 2 shows higher programming speed but lower erasing speed than Comparative Embodiment 1. However, as shown in FIGS. 8 and 9, it can be found that Embodiment 1 shows higher programming speed as well as erasing speed than Comparative Embodiments 1 and 2.

### Experimental Embodiment 2

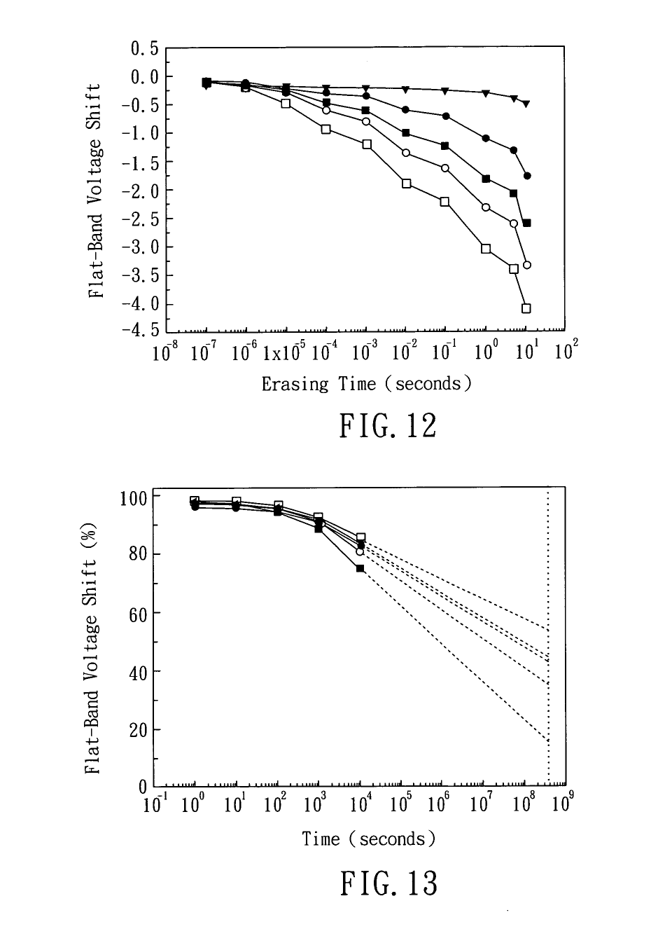

The charge trapping devices according to Embodiments 2 and 3 and Comparative Embodiments 3, 4 and 5 are operated by channel Fowler-Nordheim (F-N) programming/erasing and the flat-band voltage shift (ΔVfb) is measured so as to evaluate the operation characteristics and charge retention of the charge trapping devices according to Embodiments 2 and 3 and Comparative Embodiments 3, 4 and 5. FIGS. 11, 12 and 13 respectively show a flat-band voltage shift vs. programming time diagram by F-N of 10V, a flat-band voltage shift vs. erasing time diagram by F-N of −10V, and a flat-band voltage shift (%) vs. time diagram.

From the results shown in FIGS. 11 to 13, it can be confirmed that the charge trapping devices according to Embodiments 2 and 3 exhibit higher programming speed as well as erasing speed in comparison with Comparative Embodiments 3, 4 and 5, and present excellent charge retention. Additionally, in view of the curves of Embodiment 2 and Comparative Embodiment 3, it can be known that the general concept that the programming speed can be enhanced only by first stacking a charge trapping layer with a small conduction band offset is denied.

### Experimental Embodiment 3

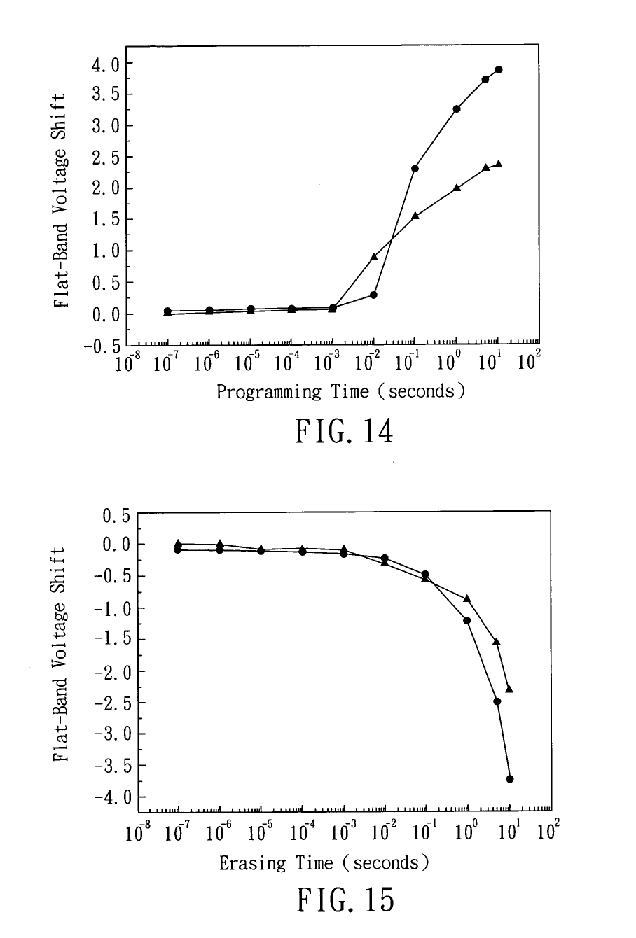

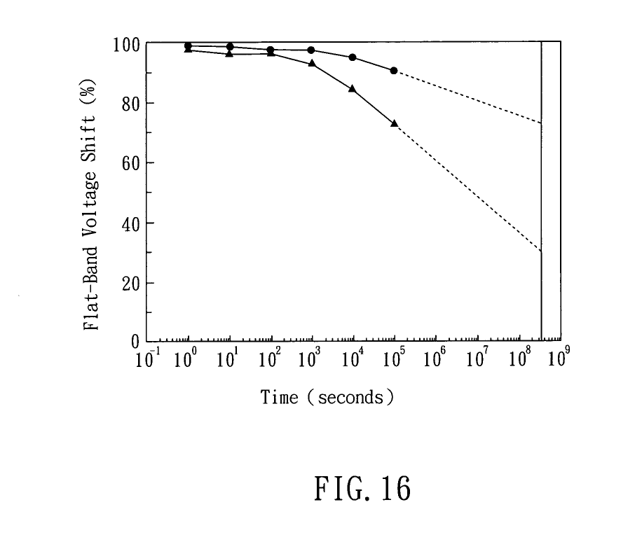

The charge trapping devices according to Embodiment 4 and Comparative Embodiment 6 are operated by channel Fowler-Nordheim (F-N) programming/erasing and the flat-band voltage shift (ΔVfb) is measured so as to evaluate the operation characteristics and charge retention of the charge trapping devices according to Embodiment 4 and Comparative Embodiment 6. FIGS. 14, 15 and 16 respectively show a flat-band voltage shift vs. programming time diagram by F-N of 10V, a flat-band voltage shift vs. erasing time diagram by F-N of −10V, and a flat-band voltage shift (%) vs. time diagram.

From the results shown in FIGS. 14 to 16, it can be confirmed that the charge trapping device according to Embodiment 4 exhibits higher programming speed as well as erasing speed than those according to Comparative Embodiment 6, and presents improved charge retention in comparison with Comparative Embodiment 6.

Accordingly, the above-mentioned experiments can prove that the stacked type charge trapping layer according to the present invention can significantly improve the programming speed and erasing speed of a charge trapping device in comparison with a charge trapping device with a single-layered charge trapping layer. In addition, the charge trapping device provided by the present invention can present excellent charge retention. Particularly, the present invention provides the idea that a dielectric layer with a smaller conduction band offset is stacked after a dielectric layer with a larger conduction band offset so as to enhance the programming speed as well as the erasing speed of a charge trapping device. Thereby, the present invention can improve the situation observed in conventional charge trapping devices that the programming speed is large while the erasing speed is small. Moreover, the present invention denies the general concept that the programming speed can be enhanced only by first stacking a charge trapping layer with a small conduction band offset.

Although the present invention has been explained in relation to its preferred embodiment, it is to be understood that many other possible modifications and variations can be made without departing from the spirit and scope of the invention as hereinafter claimed.

What is claimed is:

1. A charge trapping device, comprising:
a substrate, having a first surface and an opposite second surface;
a tunneling insulating layer, disposed on the first surface of the substrate;
a charge trapping layer, disposed on the tunneling insulating layer and including a first dielectric layer and a second dielectric layer, in which the first dielectric layer is connected to the tunneling insulating layer, the second dielectric layer is disposed over the first dielectric layer, and a conduction band offset between the first dielectric layer and the substrate is larger than that between the second dielectric layer and the substrate; and
a blocking insulating layer, disposed on the charge trapping layer and connected to the second dielectric layer.

2. The charge trapping device as claimed in claim 1, wherein the material of the first dielectric layer is silicon nitride, hafnium oxide, hafnium aluminum oxide or hafnium silicate.

3. The charge trapping device as claimed in claim 1, wherein the material of the second dielectric layer is hafnium oxide, hafnium aluminum oxide or hafnium silicate.

4. The charge trapping device as claimed in claim 1, wherein the materials of the first dielectric layer and the second dielectric layer respectively are silicon nitride and hafnium oxide; hafnium aluminum oxide and hafnium oxide; hafnium oxide and hafnium silicate; hafnium aluminum oxide and hafnium aluminum oxide, in which the aluminum/hafnium ratio of the first dielectric layer is larger than that of the second dielectric layer; or hafnium silicate and hafnium silicate, in which the silicon/hafnium ratio of the first dielectric layer is smaller than that of the second dielectric layer.

5. The charge trapping device as claimed in claim 1, further comprising: a control gate, disposed on the blocking insulating layer.

6. The charge trapping device as claimed in claim 5, further comprising: a first electrode and a second electrode, respectively connected to the control gate and the second surface of the substrate.

7. The charge trapping device as claimed in claim 1, wherein the substrate has a source and a drain.

8. The charge trapping device as claimed in claim 1, wherein the substrate is an Si substrate.

9. The charge trapping device as claimed in claim 1, wherein the material of the tunneling insulating layer is SiO₂.

10. The charge trapping device as claimed in claim 1, wherein the material of the blocking insulating layer is Al₂O₃.

11. The charge trapping device as claimed in claim 5, wherein the material of the control gate is TaN.

12. A method for manufacturing a charge trapping device, comprising:
providing a substrate having a first surface and an opposite second surface;
forming a tunneling insulating layer on the first surface of the substrate;
forming a charge trapping layer on the tunneling insulating layer, wherein the charge trapping layer includes a first dielectric layer and a second dielectric layer, the first dielectric layer is connected to the tunneling insulating layer, the second dielectric layer is disposed over the first dielectric layer, and a conduction band offset between the first dielectric layer and the substrate is larger than that between the second dielectric layer and the substrate; and
forming a blocking insulating layer on the charge trapping layer, wherein the blocking insulating layer is connected to the second dielectric layer.

13. The method for manufacturing a charge trapping device as claimed in claim 12, wherein the material of the first dielectric layer is silicon nitride, hafnium oxide, hafnium aluminum oxide or hafnium silicate.

14. The method for manufacturing a charge trapping device as claimed in claim 12, wherein the material of the second dielectric layer is hafnium oxide, hafnium aluminum oxide or hafnium silicate.

15. The method for manufacturing a charge trapping device as claimed in claim 12, wherein the materials of the first dielectric layer and the second dielectric layer respectively are silicon nitride and hafnium oxide; hafnium aluminum oxide and hafnium oxide; hafnium oxide and hafnium silicate; hafnium aluminum oxide and hafnium aluminum oxide, in which the aluminum/hafnium ratio of the first dielectric layer is larger than that of the second dielectric layer; or hafnium silicate and hafnium silicate, in which the silicon/hafnium ratio of the first dielectric layer is smaller than that of the second dielectric layer.

16. The method for manufacturing a charge trapping device as claimed in claim 12, further comprising: forming a control gate on the blocking insulating layer.

17. The method for manufacturing a charge trapping device as claimed in claim 16, further comprising: respectively forming a first electrode and a second electrode on the control gate and the second surface of the substrate.

18. The method for manufacturing a charge trapping device as claimed in claim 12, wherein the substrate has a source and a drain.

19. The method for manufacturing a charge trapping device as claimed in claim 12, wherein the charge trapping layer is formed by chemical vapor deposition.

20. The method for manufacturing a charge trapping device as claimed in claim 12, wherein the substrate is an Si substrate.

21. The method for manufacturing a charge trapping device as claimed in claim 12, wherein the material of the tunneling insulating layer is SiO₂.

22. The method for manufacturing a charge trapping device as claimed in claim 12, wherein the material of the blocking insulating layer is Al₂O₃.

23. The method for manufacturing a charge trapping device as claimed in claim 16, wherein the material of the control gate is TaN.
